(19) United States
(12) Patent Application Publication
(10) Pub. No.: US 2006/0157826 A1
(43) Pub. Date: Jul. 20, 2006

(54) Multi-path printed circuit board having heterogeneous layers and power delivery system including the same

(76) Inventors: Hee-seok Lee, Hwaseong-si (KR); Un-byoung Kang, Hwaseong-si (KR); Yun-hyeok Im, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/247,307

(22) Filed: Oct. 12, 2005

(30) Foreign Application Priority Data
Oct. 12, 2004 (KR) 2004-0081407

(51) Int. Cl. H01L 23/58

(52) U.S. Cl. 257/635

(57) ABSTRACT

A multi-path printed circuit board (PCB) comprising separate direct current (DC) and alternating current (AC) paths, and a power delivery system including the same are provided. The multi-path PCB comprises a plurality of planar layers, each comprising a metal layer, and a plurality of insulators interposed between the planar layers. The metal layers may have different conductivities. The power delivery system includes a power source, a semiconductor IC, and the multi-path PCB. The multi-path PCB is adapted to function as a power delivery path for delivering power from the power source to the semiconductor IC.

### BACKGROUND OF THE INVENTION

1. Field of the Invention

The present invention relates to a multi-layered printed circuit board (PCB) and a semiconductor device including the same, and more particularly, to a multi-layered printed circuit board (PCB) including heterogeneous layers having different electrical conductivities and a power delivery system including the same.

This application claims priority to Korean Patent Application No. 10-2004-0081407, filed on Oct. 12, 2004, the subject matter of which is hereby incorporated by reference in its entirety.

2. Description of the Related Art

Packaging techniques and interconnection design techniques for semiconductor integrated circuits have been developed in response to needs for miniaturization and packaging reliability of such circuits. For example, a printed circuit board (PCB), which is usually associated with a ball grid array (BGA) package, including at least a planar layer has been developed. In this case, each planar layer comprises a metal layer providing a mechanical supporting structure and an electrical connection structure for electronic components.

Conventionally, all of the metal layers of a PCB are formed from the same metal, and are often formed from copper (Cu). For example, a BGA package having a four-layer planar structure or a system-board design includes a PCB in which all of the metal layers are formed from Cu. Conventionally, a PCB having a four-layer planar structure includes two intermediate planar layers. One of the two intermediate planar layers is designated as a ground plane, and the other is designed as a power plane.

However, when metal layers of a PCB are formed from the same metal material, significant power noise occurs at a frequency where power plane resonance and ground plane resonance occur, thus generating a large amount of simultaneous switching noise (SSN). Therefore, a system comprising the PCB having metal layers formed from the same material may malfunction, causing deterioration of system-level performance. Electro-magnetic interference (EMI) may occur in such a system as well.

### SUMMARY OF THE INVENTION

In one embodiment, the invention provides a multi-path printed circuit board comprising a first planar layer comprising a first metal layer having a first electrical conductivity, a second planar layer comprising a second metal layer having a second electrical conductivity, wherein the first planar layer is on the second planar layer, and an intermediate layer, wherein the first planar layer is on the intermediate layer, and the intermediate layer is on the second planar layer.

In another embodiment, the invention provides a power delivery system comprising a power source, a semiconductor integrated circuit (IC), and a multi-path printed circuit board configured to function as a power supply path for delivering power from the power source to the semiconductor IC, and comprising a direct current (DC) path and an alternating current (AC) path, wherein the DC path and the AC path are separate.

### BRIEF DESCRIPTION OF THE DRAWINGS

Exemplary embodiments of the invention will be described in detail with reference to the accompanying drawings, in which like reference symbols indicate like elements. In the drawings:

FIG. 1 is a block diagram of a power delivery system according to an exemplary embodiment of the invention;

FIG. 2 is a sectional view of a multi-path printed circuit board (PCB) in accordance with an embodiment of the invention;

FIG. 3 is a sectional view of a multi-path PCB in accordance with another embodiment of the invention;

FIG. 4 is a sectional view of a multi-path PCB in accordance with yet another embodiment of the invention;

FIG. 5 is a sectional view of a multi-path PCB in accordance with still another embodiment of the invention;

FIG. 6 is a graph illustrating resonance characteristics when a multi-path PCB in accordance with embodiments of the invention is used to deliver (e.g., transfer) power to a ball grid array (BGA) package;

FIG. 7A is a graph illustrating capacitance per unit length when multi-path PCBs in accordance with an embodiment of the invention and when a multi-path PCB in accordance with the conventional art are used to deliver a power source to a BGA package;

FIG. 7B is a graph illustrating inductance per unit length when a multi-path PCB in accordance with an embodiment of the invention and when a multi-path PCB in accordance with the conventional art are used to deliver power to a BGA package;

FIG. 7C is a graph illustrating resistance per unit length when a multi-path PCB in accordance with an embodiment of the invention and when a multi-path PCB in accordance with the conventional art are used to deliver power to a BGA package; and

FIG. 7D is a graph illustrating impedance when a multi-path PCB in accordance with an embodiment of the invention and when a multi-path PCB in accordance with the conventional art are used to deliver power to a BGA package.

### DESCRIPTION OF EXEMPLARY EMBODIMENTS

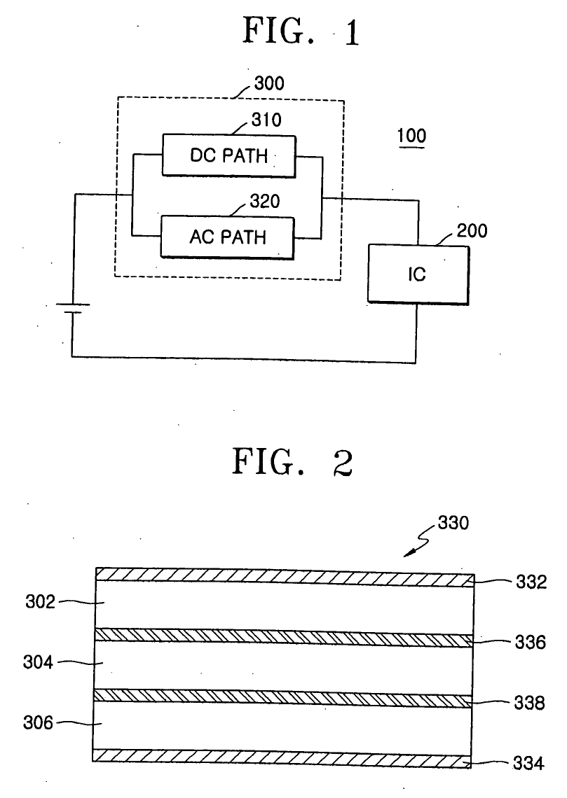

FIG. 1 is a block diagram of a power delivery system 100 in accordance with an exemplary embodiment of the invention.

Referring to FIG. 1, power delivery system 100 includes a semiconductor integrated circuit (IC) 200, and a multi-path printed circuit board (PCB) 300 adapted for use as a power delivery path for delivering power from a power source to semiconductor IC 200.

Semiconductor IC 200 may be, for example, a packaged semiconductor chip or a packaged semiconductor die.

In multi-path PCB 300, a direct current (DC) signal is delivered to semiconductor IC 200 via a DC path 310, and an alternating current (AC) signal, which is a high frequency signal, is delivered to semiconductor IC 200 via an AC path 320. So, DC and AC signals provided to semiconductor IC 200 pass through separate paths in multi-path PCB 300. DC path 310 and AC path 320 each comprise a metal layer, and the metal layer of DC path 310 has a greater electrical conductivity than the metal layer of AC path 320. For example, DC path 310 may be formed from copper (Cu), and AC path 320 may be formed from nickel (Ni). In this exemplary embodiment, the electrical conductivity of Cu may be about 5.8E7 mho/m. The electrical conductivity of Ni may be about 1.45E7 mho/m.

As used herein, a “metal layer” may comprise a single metal or any combination of two or more metals or other substances.

Since DC path 310 comprises a high-conductivity metal layer, the DC power supply level may be maintained. In addition, since AC path 320 comprises a low-conductivity metal layer, a high frequency current, which is produced by the switching of a complementary metal oxide semiconductor (CMOS) in semiconductor IC 200, can be induced to flow along AC path 320. Therefore, high frequency noise of a signal line is reduced.

The terms high-conductivity and low-conductivity are relative terms wherein the electrical conductivity of a high-conductivity component is high relative to the electrical conductivity of a low-conductivity component, and wherein the electrical conductivity of a low-conductivity component is low relative to the electrical conductivity of a high-conductivity component. Furthermore, various high-conductivity components may have different electrical conductivities, and likewise various low-conductivity components may have different electrical conductivities.

DC path 310 of multi-path PCB 300 comprises an interconnection pattern with a relatively small width. When a power network or a ground network is formed in the same plane as DC path 310, the power network or the ground network may be formed as sparsely as possible. On the other hand, AC path 320 is designed as a power plane or a ground plane with a relatively large width and a relatively low inductance. In detail, AC path 320 has a larger width than DC path 310, and has a relatively low inductance due to the high resistance of the low-conductivity metal of AC path 320. As a result, a low quality factor (Q) can be obtained, which is desirable for a high-frequency power delivery network. In addition, an IR-drop can be effectively decreased in DC path 310.

Since DC path 310 and AC path 320 are separate in power delivery system 100, a DC-IR drop can be prevented and signal-delivering characteristics of DC path 310 can be maintained.

FIG. 2 is a sectional view of a multi-path PCB 330 in accordance with an embodiment of the invention, which can be used as multi-path PCB 300 of power delivery system 100 in FIG. 1. Multi-path PCB 330 comprises a four-layer plane.

Referring to FIG. 2, multi-path PCB 330 comprises a DC path and an AC path. The DC path comprises a first high-conductivity metal layer 332 and a second high-conductivity metal layer 334. The AC path comprises a first low-conductivity metal layer 336 and a second low-conductivity metal layer 338. First high-conductivity metal layer 332 and second high-conductivity metal layer 334 are each formed from a material with a relatively high electrical conductivity, such as Cu. First low-conductivity metal layer 336 and second low-conductivity metal layer 338 are each formed from a material with a relatively low electrical conductivity, such as Ni. In FIG. 2, the intermediate metal layers, first and second low-conductivity metal layers 336 and 338, are formed from material having a relatively low electrical conductivity.

Intermediate metal layers are layers that are between first high-conductivity metal layer 332 and second high-conductivity metal layer 334. First high-conductivity metal layer 332 is on the intermediate metal layers, and the intermediate metal layers are on second high-conductivity metal layer 334. As used herein, the term “on” means directly on, or on with one or more intervening layers.

In FIG. 2, first high-conductivity metal layer 332 and second high-conductivity metal layer 334 may constitute a signal line of a power delivery system. First low-conductivity metal layer 336 may constitute a ground plane of the signal line, and second low-conductivity metal layer 338 may constitute a power plane. First high-conductivity metal layer 332, which serves as a signal line, is preferably adjacent to a low-conductivity metal layer, with one insulator in between.

As used herein, the term “adjacent” means directly adjacent to or adjacent with one or more intervening layers. Also, an “insulator” may comprise a single insulating material or any combination of two or more insulating materials.

The multi-path PCB 330 also includes insulators 302, 304, and 306. Insulators 302, 304, and 306 may be formed from, for example, FR-4.

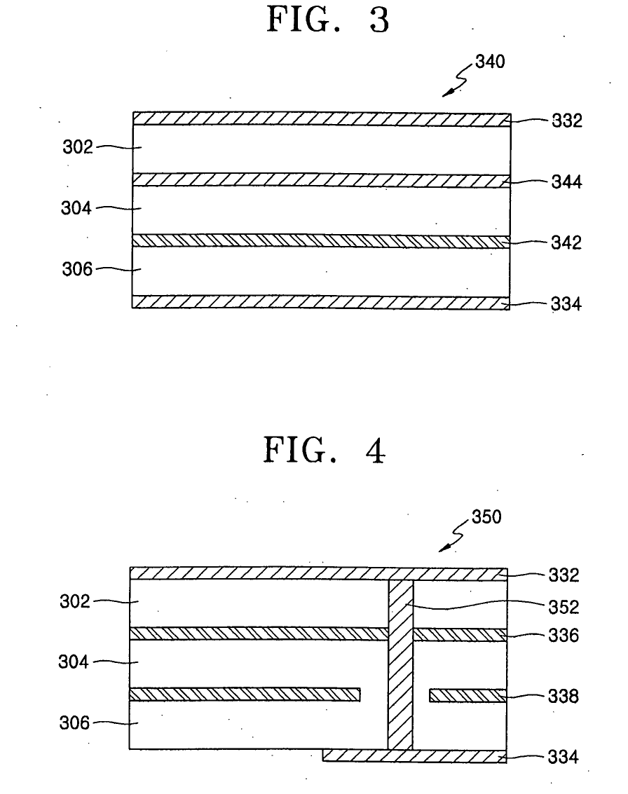

FIG. 3 is a sectional view of a multi-path PCB 340 in accordance with another embodiment of the invention. Multi-path PCB 340 shown in FIG. 3 is the same as multi-path 330 PCB shown in FIG. 2, except that only one of the two intermediate layers 342 and 344 is a low-conductivity metal layer.

Referring to FIG. 3, multi-path PCB 340 has a four-layer planar structure comprising an intermediate planar that comprises a low-conductivity metal layer 342 and a high-conductivity metal layer 344. In this exemplary embodiment, the DC path comprises high-conductivity metal layers 332, 334, and 344; and the AC path comprises low-conductivity metal layer 342. High-conductivity metal layers 332, 334, and 344 may be formed from Cu, for example, and low-conductivity metal layer 342 may be formed from Ni, for example.

FIG. 4 is a sectional view of a multi-path PCB 350 in accordance with yet another embodiment of the invention. Multi-path PCB 350 shown in FIG. 4 is the same as multi-path PCB 330 shown in FIG. 2, except that first high-conductivity metal layer 332 is connected to second high-conductivity metal layer 334 by a via contact plug 352 penetrating the two intermediate layers of multi-path PCB 350.

In multi-path PCB 350 shown in FIG. 4, when first high-conductivity metal layer 332 and second high-conductivity metal layer 334 are formed from Cu and first low-conductivity metal layer 336 and second low-conductivity metal layer 338 are formed from Ni, via contact plug 352 may be formed from any one of Cu and Ni because inter-metal connections can be easily obtained with either Cu or Ni due to their excellent adherence characteristics. In this exemplary embodiment, as shown in FIG. 4, via contact plug 352 and first and second high-conductivity metal layers 332 and 334 are formed from the same high-conductivity metal material.

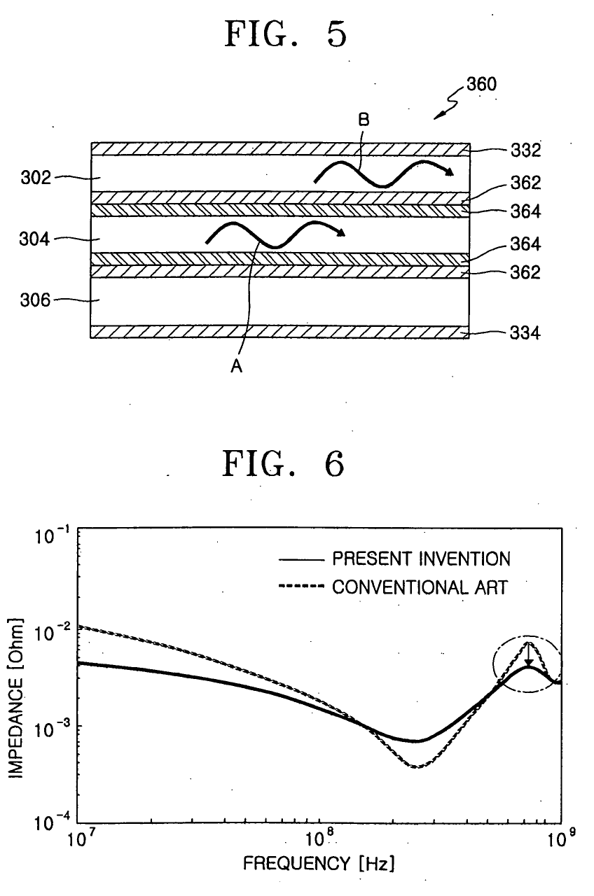

FIG. 5 is a sectional view of a multi-path PCB 360 in accordance with still another embodiment of the invention. Multi-path PCB 360 shown in FIG. 5 is the same as multi-path PCB 330 shown in FIG. 2, except that each of the two intermediate layers is a heterogeneous metal complex layer composed of a high-conductivity metal layer 362 and a low-conductivity metal layer 364.

In multi-path PCB 360, high-conductivity metal layers 362 may be formed from Cu, for example, and low-conductivity metal layers 364 may be formed from Ni, for example. In the intermediate layers of multi-path PCB 360, which functions as a power delivery network, only low-conductivity metal layers 364 affect high frequency simultaneous switching noise (SSN) due to a skin effect. Thus, power is delivered through a path denoted by an arrow A shown in FIG. 5. That is, in FIG. 5, an AC path comprises the two low-conductivity metal layers 364 and insulator 304 interposed in between. In addition, an arrow B shown in FIG. 5 denotes a signal delivery path. In this exemplary embodiment two DC paths are formed. A first DC path comprises high-conductivity metal layers 332 and 362 and insulator 302 interposed in between, and a second DC path comprises high-conductivity metal layers 334 and 362 and insulator 306 interposed in between.

As illustrated in the previously described exemplary embodiments, when the multi-path PCB includes a heterogeneous metal layer, a ground plane or a power plane comprises a low-conductivity metal layer, and a high-conductivity metal layer constitutes a signal line. Therefore, electrical loss of the signal line can be minimized or effectively reduced.

Although Cu is used as an exemplary high-conductivity metal and Ni is used as an exemplary low-conductivity metal in the exemplary embodiments illustrated in FIGS. 2 through 5, the invention is not limited to these materials. Rather, various metal combinations with different electrical conductivities may be used in a multi-path PCB without departing from the scope of the invention. For example, when Cu is used as a high-conductivity metal to form DC path 310 of a multi-path PCB, titanium (Ti) or lead (Pb), in addition to Ni, may be used as a low-conductivity metal to form AC path 320.

In addition, although the PCBs shown and described in the exemplary embodiments of FIGS. 2 through 5 each have a four-layer planar structure, the invention is not limited thereto. Rather, embodiments of the invention may comprise a multi-layer planar structure consisting of six layers, eight layers, ten layers, etc., while remaining within the scope of the invention as claimed. Such variations will be apparent to those of ordinary skill in the art.

FIG. 6 is graph illustrating resonance characteristics when a multi-path PCB in accordance with an embodiment of the invention is used to deliver power to a ball grid array (BGA) package. A PCB with the four-layer planar structure shown in FIG. 2 was used in relation to FIG. 6. First high-conductivity metal layer 332 and second high-conductivity metal layer 334 of the PCB were formed from Cu, and first low-conductivity metal layer 336 and second low-conductivity metal layer 338 were formed from Ni. A conventional PCB was used as a comparative example. All of the planar layers of the conventional PCB were formed from Cu.

Referring to FIG. 6, for the conventional PCB, the impedance peaked at a resonance frequency of a power supply system. Therefore, the conventional PCB is very susceptible to power noise and electromagnetic interference (EMI). On the other hand, for the multi-path PCB in accordance with an embodiment of the invention, the impedance at the resonance frequency of the power supply system was relatively less than that of the conventional PCB and was not as extreme. As a result, simultaneous switching noise (SSN) was relatively reduced in the multi-path PCB in accordance with an embodiment of the invention.

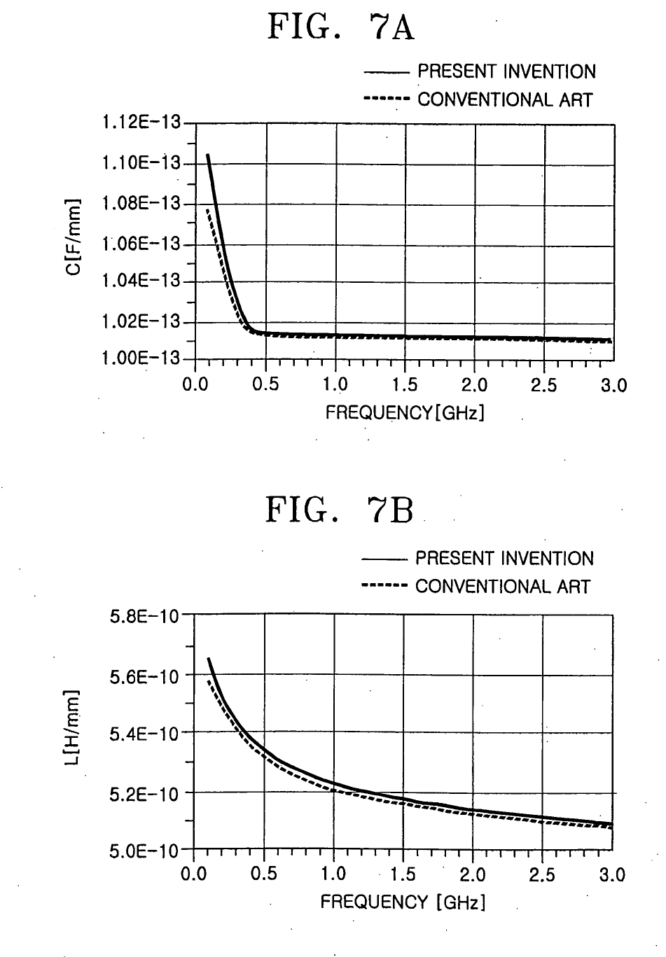

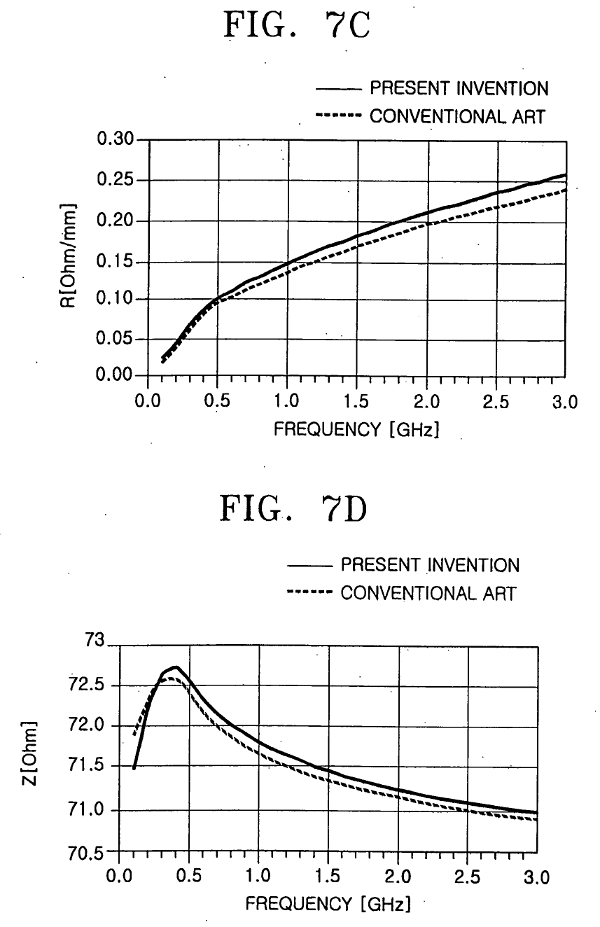

FIGS. 7A through 7D are graphs illustrating electrical characteristics of signal lines of a power delivery system including a multi-path PCB in accordance with an embodiment of the invention, and of signal lines of a power delivery system including a conventional multi-path PCB. Both the power delivery system in accordance with an embodiment of the invention and the conventional power delivery system of FIGS. 7A through 7D are the same as those used in relation to FIG. 6.

Specifically, FIG. 7A illustrates a capacitance per unit length of a signal line with respect to frequency, FIG. 7B illustrates an inductance per unit length of a signal line with respect to frequency, FIG. 7C illustrate a resistance per unit length of a signal line with respect to frequency, and FIG. 7D illustrate impedance with respect to frequency.

Referring to FIGS. 7A through 7D, the electrical loss of the signal line of the power delivery system in accordance with an embodiment of the present invention is no greater than 5%. An electrical loss of less than 5% is sufficiently small for a semiconductor device to maintain electrical characteristics.

When the results illustrated in FIGS. 7A through 7D are considered, the following effect is apparent regarding an embodiment of the invention. When a power plane layer and a ground plane layer are formed from a low-conductivity metal, as in a multi-path PCB in accordance with an embodiment of the invention, adverse effects on electrical characteristics of a signal line can be maintained at a level low enough that electrical characteristics of the device are maintained. In addition, since the power plane layer and the ground plane layer are formed from a low-conductivity metal, a DC path and an AC path are separate in a power delivery system. The separation of the DC path and the AC path results in suppression of impedance, thus reducing resonance in the power delivery system.

Embodiments of the invention provide a multi-path PCB, in which a DC path and an AC path are separate, and a power delivery system including the same. The separation of the DC path and the AC path yields many benefits. For example, electrical characteristics of a signal line can be maintained when a DC signal is provided, and high frequency power noise and high frequency resonance can be effectively suppressed. In order to embody an optimized signal line design in accordance with the respective requirements of the DC path and the AC path, the DC path comprises a high-conductivity metal, and the AC path comprises a low-conductivity metal. As a result, the AC path may have a low quality factor (Q), which is desirable for a high frequency power delivery network, and the DC path may have a low IR-drop. Accordingly, the multi-path PCB in accordance with embodiments of the invention has a plurality of planar layers, each comprising a metal layer, and the electrical conductivity of each metal layer corresponds with the function of its corresponding planar layer. As a result, the multi-path PCB having the above-mentioned structure can deliver (e.g., transfer) power more effectively relative to conventional PCBs.

While the present invention has been particularly shown and described with reference to exemplary embodiments, it will be understood by those of ordinary skill in the art that various changes and modifications may be made therein without departing from the scope of the invention as defined by the following claims.

What is claimed is:

1. A multi-path printed circuit board comprising:
a first planar layer comprising a first metal layer having a first conductivity formed on a second planar layer comprising a second metal layer having a second conductivity; and,
an intermediate layer formed between the first planar layer and the second planar layer.

2. The multi-path printed circuit board of claim 1, wherein the intermediate layer comprises a first intermediate planar layer and a second intermediate planar layer,
wherein the first intermediate planar layer comprises a third metal layer having a third conductivity, and the second intermediate planar layer comprises a fourth metal layer having a fourth conductivity;
wherein the third and fourth conductivities are each respectively less than the first and second conductivities.

3. The multi-path printed circuit board of claim 1, wherein the first metal layer and the second metal layer are each formed from copper (Cu).

4. The multi-path printed circuit board of claim 2, wherein the third metal layer and the fourth metal layer are each formed from nickel (Ni), titanium (Ti), or lead (Pb).

5. The multi-path printed circuit board of claim 2, wherein the third metal layer has a larger width than the first metal layer.

6. The multi-path printed circuit board of claim 1, wherein the first planar layer constitutes a signal line adapted to transfer a direct current signal.

7. The multi-path printed circuit board of claim 6, wherein the first intermediate planar layer comprises a ground plane adapted to transfer an alternating current signal.

8. The multi-path printed circuit board of claim 6, wherein the first intermediate planar layer comprises a power plane adapted to transfer an alternating current signal.

9. The multi-path printed circuit board of claim 6, further comprising:
an insulator is interposed between the first planar layer and the first intermediate planar layer;
an insulator is interposed between the first intermediate planar layer and the second intermediate planar layer; and
an insulator is interposed between the second intermediate planar layer and the second planar layer.

10. A power delivery system comprising:
a power source;
a semiconductor integrated circuit (IC); and,
a multi-path printed circuit board (PCB) configured to function as a power supply path adapted to transfer power from the power source to the semiconductor IC, and comprising separate direct current (DC) and alternating current (AC) paths formed integral to the PCB.

11. The power delivery system of claim 10, wherein the semiconductor IC is a packaged semiconductor chip or a packaged semiconductor die.

12. The power delivery system of claim 10, wherein the multi-path PCB comprises:
a plurality of planar layers, each comprising a metal layer; and,
a plurality of insulators interposed between the planar layers,
wherein the plurality of planar layers comprises a first planar layer forming the DC path and a second planar layer forming the AC path.

13. The power delivery system of claim 12, wherein the first planar layer comprises a first metal layer having a first conductivity, and the second planar layer comprises a second metal layer having a second conductivity less than the first conductivity.

14. The multi-path printed circuit board of claim 13, wherein the first metal layer is formed from copper (Cu).

15. The multi-path printed circuit board of claim 13, wherein the second metal layer is formed from nickel (Ni), titanium (Ti), or lead (Pb).

16. The multi-path printed circuit board of claim 13, wherein the second metal layer has a larger width than the first metal layer.

17. The multi-path printed circuit board of claim 13, wherein the first planar layer comprises a signal line.

18. The multi-path printed circuit board of claim 17, wherein the second planar layer comprises a ground plane.

19. The multi-path printed circuit board of claim 17, wherein the second planar layer comprises a power plane.

20. The multi-path printed circuit board of claim 17, wherein an insulator is interposed between the first planar layer and the second planar layer.

21. The multi-path printed circuit board of claim 13, wherein the first planar layer is formed on the second planar layer and the second planar layer is formed on at least one other planar layer of the plurality of planar layers other than the first and second planar layers.
